(19) United States
(12) Patent Application Publication
(10) Pub. No.: US 2009/0139691 A1
(43) Pub. Date: Jun. 4, 2009

(54) HEAT DISSIPATION APPARATUS

(75) Inventor: GANG WEI, Shenzhen (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/967,022

(22) Filed: Dec. 29, 2007

(30) Foreign Application Priority Data
Dec. 3, 2007 (CN) 200710202831.7

(51) Int. Cl. F28F 7/00; H05K 7/20; G06F 1/20; H05K 5/00

(52) U.S. Cl. 165/80.3; 361/697

(57) ABSTRACT

A heat dissipating apparatus includes a heat sink and a fan attached to a top of the heat sink. The heat sink includes a thermally conductive base having a top surface, and a plurality of spaced thermally conductive fins extending from the top surface thereof. The fan includes a frame and at least two impellers rotatably installed inside the frame. Each of the at least two impellers slopes toward a center of the frame. Thus when airflow from the at least two impellers is blown toward the heat sink, a part of the airflow directly flows toward an inner region of the heat sink.

### BACKGROUND

1. Field of the Invention

The present invention relates to a heat dissipation apparatus, and more particularly to a heat dissipation apparatus for a computer system.

2. Description of Related Art

A heat dissipation apparatus, including a heat sink with a conductive plate and a plurality of cooling fins provided on a top of the plate, a supporter secured to a bottom of the heat sink, and a fan attached to a top of the heat sink, is known to be used for cooling heat-generating components such as central processing units (CPUs). Airflow coming from the fan is directed downwardly through the cooling fins toward the plate, thereby dissipating the heat generated by the components.

However, the most common fan used for this purpose is of the axial type. That is, a fan motor is inserted into a central hub of a bladed rotor generating the airflow, such that airflow from the fan tends to outwardly flow without affecting the column of air between the central hub and the plate. Thus, it creates in the cooling fins of the heat sink an inner region with a relatively low (or even zero) air velocity directly along the axis of the fan, and an outer region with a relatively high air velocity surrounding the inner region. With little airflow at the inner region of the heat sink, heat must be conducted laterally through the heat sink to the outer region thereof. Unfortunately, the fan is typically located right over the CPU, so that the region of poorest heat transfer is located right above the heat spot of the CPU.

What is desired, therefore, is a heat dissipation apparatus providing equally-distributed airflow to inner and outer regions of a heat sink thereof.

### SUMMARY

An exemplary heat dissipation apparatus includes a heat sink and a fan. The heat sink includes a thermally conductive base having a top surface, and a plurality of spaced thermally conductive fins extending from the top surface thereof. The fan includes a frame and at least two impellers rotatably installed inside the frame. Each of the at least two impellers slopes toward a center of the frame configured for allowing a part of the airflow from the at least two impellers directly flowing toward an inner region of the heat sink.

Other advantages and novel features of the present invention will become more apparent from the following detailed description of an embodiment when taken in conjunction with the accompanying drawings, in which:

### BRIEF DESCRIPTION OF THE DRAWINGS

FIG. 1 is an exploded view of a heat dissipation apparatus according to an embodiment, the heat dissipation apparatus including a supporter, a heat sink, and a fan;

FIG. 2 is a side-elevational view of the fan of FIG. 1;

FIG. 3 is similar to FIG. 2, but viewed from another side;

FIG. 4 is an assembled view of FIG. 1; and

FIG. 5 is a side-elevational view of FIG. 4.

### DETAILED DESCRIPTION

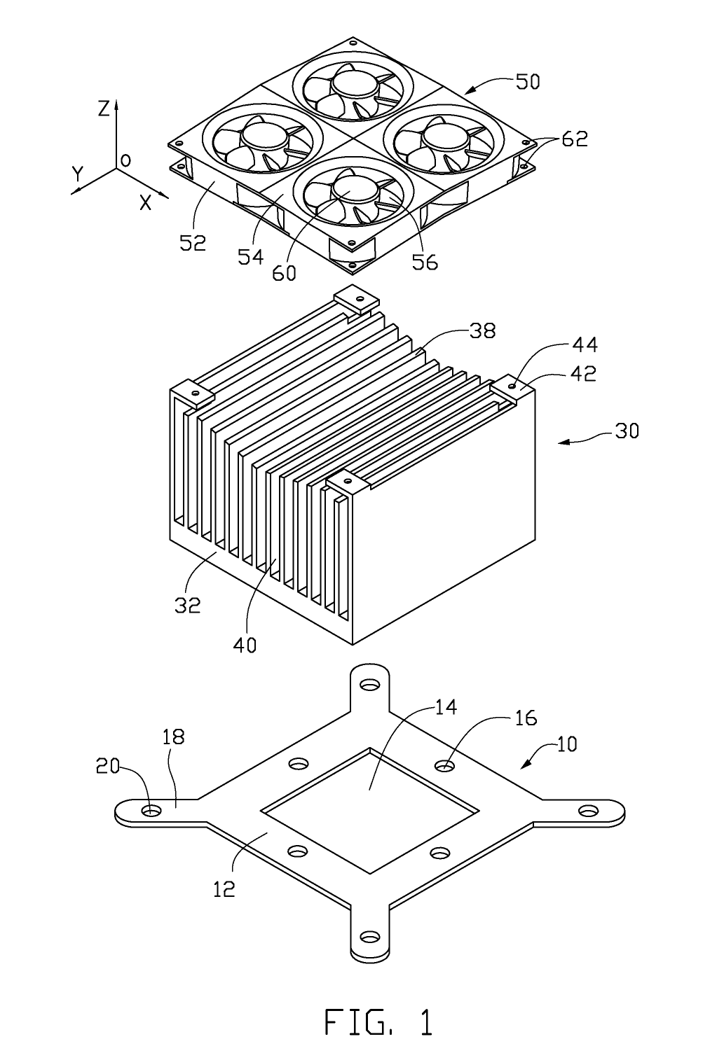

Referring to FIG. 1, in an embodiment, a heat dissipating apparatus includes a supporter 10, a heat sink 30, and a fan 50.

The supporter 10 includes a rectangular board 12 and four legs 18 respectively extending from four corners thereof. A rectangular receiving opening 14 is defined in a center of the board 12. A plurality of through holes 16 is defined in the board 12 surrounding the receiving opening 14 thereof. A fixing hole 20 is defined in each leg 18.

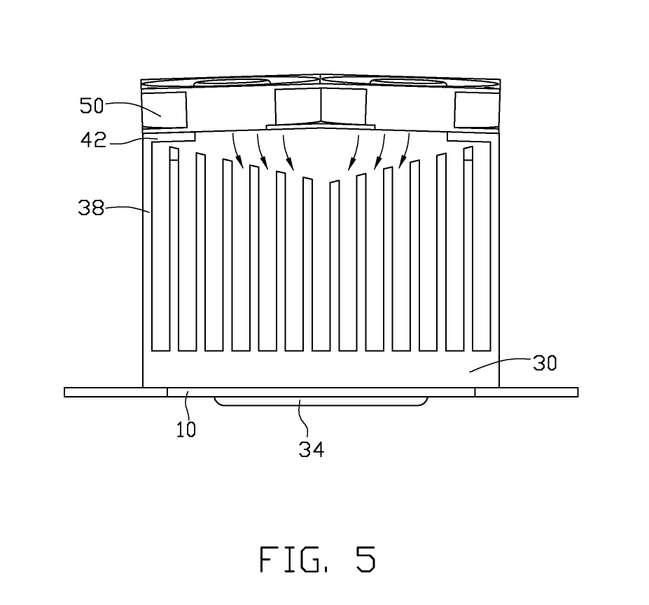

The heat sink 30 includes a thermally conductive base 32 having a top surface, and a plurality of spaced thermally conductive parallel fins 38 extending upward from the top surface thereof. A thermally conductive raised portion 34 (see FIG. 5) is formed on a bottom surface of the base 32 for being received in the receiving opening 14 of the supporter 10 and abutted onto a top surface of a heat-generating component such as a central processing unit (CPU). A plurality of mounting holes (not visible) is defined in the bottom surface of the base 32 surrounding the raised portion 34 thereof. An air channel 40 is formed between every two adjacent fins 38. Heights of the parallel fins 38 gradually decrease from two outermost fins 38 at each side of the heat sink 30 to the intermediate fins 38 between the two outermost fins 38, thereby the parallel fins 38 together form a generally V-shaped profile (see FIG. 5) at the top thereof. Two installing portions 42 are bent from a top of each outermost fin 38. An installing hole 44 is defined in each installing portion 42.

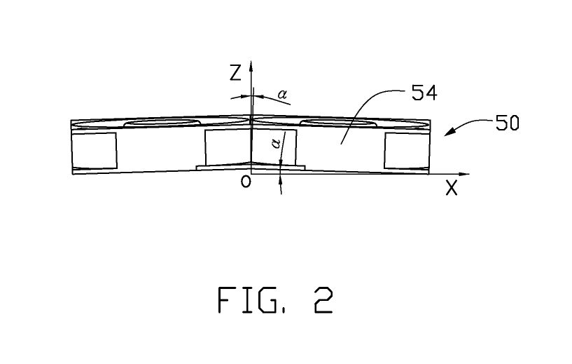

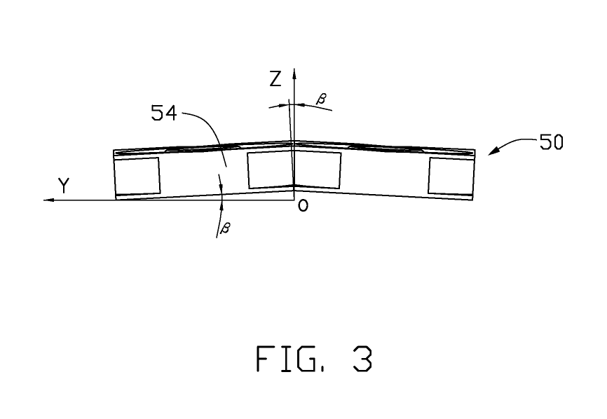

Referring also to FIGS. 2 and 3, the fan 50 includes an exterior frame 52 and four impellers 60 installed inside the frame 52. A three-dimensional XYZ coordinate system is shown on the frame 52 with the origin O thereof at a center of the frame 52. The frame 52 includes four sloping sections 54 arrayed together, and each sloping section 54 is positioned at an inclined surface in the XYZ coordinate system. A projection of a normal line of the inclined surface projected on the ZX coordinate plane forms an angle α with respect to the Z coordinate axis and a projection of the normal line of the inclined surface projected on the YZ coordinate plane forms an angle β with respect to the Z coordinate axis, and the four sloping sections 54 of the frame 52 slope toward the center thereof. Here, α=2°˜5°, and β=2°˜5°. An installing opening 56 is defined in each sloping section 54 of the frame 52. A support structure (not visible) is formed on a bottom of each sloping section 54 of the frame 52 and below the corresponding installing opening 56 thereof. The four impellers 60 are respectively received in the installing openings 56 of the frame 52 and rotatably mounted to the corresponding securing structures thereof. Thus the four impellers 60 slope toward the center of the frame 52. A mounting hole 62 is defined in each of the four corners of the frame 52.

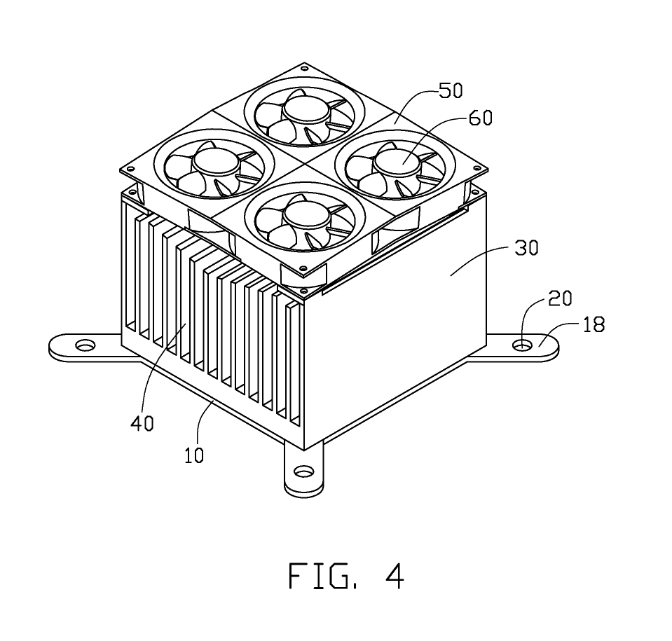

Referring also to FIGS. 4 and 5, in assembly, the raised portion 34 of the base 32 of the heat sink 30 is received in the receiving opening 14 of the supporter 10, and the mounting holes of the base 32 are respectively aligned with the through holes 16 of the supporter 10. A plurality of fasteners (not visible) such as screws is passed through the through holes 16 of the supporter 10 and screwed into the mounting holes of the base 32 respectively. Thus the supporter 10 is attached to the heat sink 30. Four fasteners (not shown) are respectively passed through the mounting holes 62 of the fan 50 and secured in the installing holes 44 of the installing portions 42 of the heat sink 30, thereby the fan 50 is fixed to the top of the heat sink 30.

Thus, the four impellers 60 of the fan 50 slope toward an inner region of the heat sink 30 simultaneously. Forced airflow as indicated by a set of arrows from the impellers 60 flows toward the heat sink 30 from four different directions, and simultaneously a part of the airflow directly flows toward the inner region of the heat sink 30 from tops of the parallel fins 38 to the base 32 thereof. Heated air between the parallel fins 38 is dissipated away from the heat sink 30. And a gap is defined between the top of the heat sink 30 and the fan 50, because of the V-shaped top of the heat sink 30. Resistance of the top of the heat sink 30 to the airflow is relatively reduced such that more air can flow toward the inner region of the heat sink 30. Thus the forced airflow from the fan 50 can be equally distributed to every region of the heat sink 30, thereby efficiently removing heat from a heat-generating component attached under the raised portion 34 of the heat sink 30. Additionally, the fan 50 has four impellers 60, even if some of the impellers 60 stop working during operation, the remaining impellers 60 can blow air toward the heat sink 30. Thus, the heat dissipation apparatus is more reliable.

A plurality of rubber washers may be sandwiched between the installing portions 42 of the heat sink 30 and the corresponding corners of the fan 50 for absorbing vibration generated by the fan 50 during operation.

The top of the heat sink 30 may have a downwardly-arcuate or truncated cone profile, or be depressed at the center thereof to facilitate air from the fan 50 flowing toward the inner region of the heat sink 30.

Alternatively, the four sections 54 of the frame 52 may be located at a horizontal surface in the XYZ coordinate system, and the impellers 60 positioned at the corresponding inclined surfaces thereof. Thus when air from the fan 50 blows toward the heat sink 30, a part of the airflow can also flow toward the inner region of the heat sink 30.

The fan 50 with a plurality of impellers 60 may be replaced with a plurality of fans each having an impeller. The fans are slantingly mounted to the top of the heat sink 30 and slope toward a common center. Thus when the fans blow air toward the heat sink 30, a part of the airflow can flow toward the inner region of the heat sink 30.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus comprising:
a heat sink comprising a thermally conductive base having a top surface, and a plurality of spaced thermally conductive fins extending from the top surface thereof; and
a fan attached to a top of the heat sink and comprising a frame and at least two impellers rotatably installed inside the frame, said at least two impellers sloping toward a center of the frame configured for a part of airflow from said at least two impellers directly flowing toward an inner region of the heat sink.

2. The heat dissipation apparatus as described in claim 1, wherein when a presumptive three-dimensional XYZ coordinate system is set on the frame with the XY coordinate plane being parallel to a bottom surface of the heat sink and the origin O thereof being aligned with the center of the frame, each of said at least two impellers of the fan being positioned at an inclined surface in the XYZ coordinate system, and a projection of a normal line of the inclined surface projected on the ZX coordinate plane forms an angle of 2 to 5 degrees with respect to the Z coordinate axis and a projection of the normal line of the inclined surface projected on the YZ coordinate plane forms an angle of 2 to 5 degrees with respect to the Z coordinate axis.

3. The heat dissipation apparatus as described in claim 1, wherein the frame comprises at least two sloping sections sloping toward the center thereof, and each of said at least two sloping sections defining an installing opening therein for receiving one corresponding impeller.

4. The heat dissipation apparatus as described in claim 3, wherein a plurality of installing holes is defined in the top of the heat sink, a plurality of mounting holes is defined in the frame, and a plurality of fasteners is respectively passed through the mounting holes of the frame and engaged in the installing holes of the heat sink, thereby securing the fan to the top of the heat sink.

5. The heat dissipation apparatus as described in claim 4, wherein a plurality of installing portions is formed on the top of the heat sink, and the installing holes of the heat sink are respectively defined in the installing portions.

6. The heat dissipation apparatus as described in claim 1, wherein the top of the heat sink is depressed at the center thereof.

7. The heat dissipation apparatus as described in claim 1, wherein heights of the fins of the heat sink gradually decrease from an outer region surrounding the inner region thereof to the inner region.

8. The heat dissipation apparatus as described in claim 7, wherein the top of the heat sink has a generally V-shaped profile.

9. The heat dissipation apparatus as described in claim 7, wherein the top of the heat sink has a generally downwardly-arcuate profile.

10. A heat dissipating apparatus comprising:
a heat sink comprising a thermally conductive base having a top surface, and a plurality of spaced thermally conductive fins extending from the top surface thereof; and
at least two fans attached to a top of the heat sink and sloping toward a center of the heat sink configured for a part of airflow from said at least two fans directly flowing toward an inner region of the heat sink.

11. The heat dissipation apparatus as described in claim 10, wherein when a presumptive three-dimensional XYZ coordinate system is set on the heat sink with the XY coordinate plane being parallel to a bottom surface of the heat sink, each of said at least two fans being positioned at an inclined surface in the XYZ coordinate system, and a projection of a normal line of the inclined surface projected on the ZX coordinate plane forms an angle of 2 to 5 degrees with respect to the Z coordinate axis and a projection of the normal line of the inclined surface projected on the YZ coordinate plane forms an angle of 2 to 5 degrees with respect to the Z coordinate axis.

12. The heat dissipation apparatus as described in claim 10, wherein the top of the heat sink is depressed at the center thereof.

13. The heat dissipation apparatus as described in claim 10, wherein heights of the fins of the heat sink gradually decrease from an outer region surrounding the inner region thereof to the inner region.

14. The heat dissipation apparatus as described in claim 13, wherein the top of the heat sink has a generally V-shaped profile.

15. The heat dissipation apparatus as described in claim 13, wherein the top of the heat sink has a generally downwardly-arcuate profile.

16. The heat dissipation apparatus as described in claim 10, further comprising a supporter secured to a bottom surface of the base of the heat sink, and a plurality of fixing holes is defined in the supporter configured for fixing the heat dissipation apparatus to a desired location.
